(19) United States
(12) Patent Application Publication
(10) Pub. No.: US 2012/0199982 A1
(43) Pub. Date: Aug. 9, 2012

(54) SEMICONDUCTOR DEVICE AND METHOD OF MANUFACTURING THE SAME

(75) Inventor: Hirokazu KIKUCHI, Yokohama-shi (JP)

(73) Assignee: KABUSHIKI KAISHA TOSHIBA, Tokyo (JP)

(21) Appl. No.: 13/365,772

(22) Filed: Feb. 3, 2012

(30) Foreign Application Priority Data
Feb. 8, 2011 (JP) P2011-025266

(51) Int. Cl. H01L 23/528; H01L 21/768

(52) U.S. Cl. 257/774; 438/637; 257/E23.151; 257/E21.577

(57) ABSTRACT

A semiconductor device according to an embodiment includes: a semiconductor substrate; a plurality of interconnect layers disposed at different heights from the semiconductor substrate, each interconnect layer including an interconnection formed therein; and a via formed in a columnar shape extending in the stack direction of the interconnect layers, the via electrically connecting the interconnections of the different interconnect layers, the interconnections including a plurality of intermediate interconnections in contact with the via in the intermediate portion thereof, the intermediate interconnections including a plurality of first type intermediate interconnections passing through the via in a direction perpendicular to the stack direction, and the first type intermediate interconnection of a first one of the interconnect layer and the first type intermediate interconnection of a second one of the interconnect layer are intersecting each other in the via.

### CROSS-REFERENCE TO RELATED APPLICATIONS

This application is based upon and claims the benefit of priority from the prior Japanese Patent Application No. 2011-025266, filed on Feb. 8, 2011, the entire contents of which are incorporated herein by reference.

### FIELD

The embodiments herein relate to a semiconductor device and a method of manufacturing the same.

### BACKGROUND

Many of Semiconductor devices having a stacked structure with a plurality of stacked interconnect layers include vias for connecting an interconnection in a certain interconnect layer to an interconnection in a different interconnect layer. Some vias simply connect an upper-layer interconnection and a lower-layer interconnection. Others connect an upper-layer interconnection or an lower-layer interconnection to an intermediate interconnection formed on an intermediate portion of a via. The intermediate portion of the via is a portion between a top surface and a bottom surface thereof.

The via connected to the intermediate interconnection is formed as follows. Before forming the via, a via connection portion is formed at the end portion of the intermediate interconnection to overlap a region where the via is formed. The via connection portion is a portion of the intermediate interconnection for connecting the via. Then, before forming the upper-layer interconnection, a through-hole for embedding the via is formed until the lower-layer interconnection is reached. The through-hole is formed by etching an insulating film using a resist mask having pattern for the via formed therein until the via connection portion is exposed, and after the via connection portion is exposed, further etching using the via connection portion as a mask. In so doing, the through-hole is formed using a process by which it is easy to etch the insulating film and it is hard to etch an interconnection material. Then, a via material such as tungsten (W) is embedded into the formed through-hole. Finally, the upper-layer interconnection is formed in connection with the top surface of the via, thereby connecting the upper-layer interconnection, the intermediate interconnection, and the lower-layer interconnection via the via.

In this method, however, steps are formed in the via at a connection location with the via connection portion. The via thus thins toward the lower layers. This makes it hard to ensure sufficient contact area between the via and the lower intermediate interconnection and lower-layer interconnection. Further, misalignment between the via and the intermediate interconnection may prevent contact between the lower intermediate interconnection and the via. When using this method, therefore, an misalignment margin needs to be added to the via and the interconnection to ensure a sufficient contact area between the via and the intermediate interconnection for misalignment between the via and the interconnection. Note that, in this case, a new problem of increased chip area will arise.

As a method for solving the problem of the misalignment between the via and the interconnection, a method is proposed to remove, in the through-hole forming process, the intermediate interconnection at the same time and expose the end portion of the intermediate interconnection on the side surface of the through-hole. In this case, the formed through-hole can be embedded with an interconnection material to connect the via side surface and the intermediate interconnection end portion. This method can contact the via and the intermediate interconnection in self-alignment, thereby facilitating the alignment between the via and the interconnection.

When using this method, however, if it is hard to have a large cross sectional of the intermediate interconnection, it is also hard to ensure the sufficient contact area between the via and the intermediate interconnection, thereby increasing contact resistance.

### BRIEF DESCRIPTION OF THE DRAWINGS

FIG. 1 is a perspective view of a peripheral portion of a via of a semiconductor device according to a first embodiment;

FIG. 2 is a perspective view of the peripheral portion of the via of the semiconductor device according to the embodiment;

FIG. 3 shows an example arrangement of interconnections in the via of the semiconductor device according to the embodiment;

FIG. 4 illustrates a manufacturing process of the semiconductor device according to the embodiment;

FIG. 5 illustrates a manufacturing process of the semiconductor device according to the embodiment;

FIG. 6 illustrates a manufacturing process of the semiconductor device according to the embodiment;

FIG. 7 illustrates a manufacturing process of the semiconductor device according to the embodiment;

FIG. 8 illustrates a manufacturing process of the semiconductor device according to the embodiment;

FIG. 9 illustrates a manufacturing process of the semiconductor device according to the embodiment;

FIG. 10 illustrates a manufacturing process of the semiconductor device according to the embodiment;

FIG. 11 is a perspective view of the peripheral portion of the via of the semiconductor device according to the embodiment;

FIG. 12 shows an example arrangement of interconnections in the via of the semiconductor device according to the embodiment;

FIG. 13 shows an example arrangement of the interconnections in the via of the semiconductor device according to the embodiment;

FIG. 14 shows an example arrangement of the interconnections in the via of the semiconductor device according to the embodiment;

FIG. 15 shows an example arrangement of the interconnections in the via of the semiconductor device according to the embodiment;

FIG. 16 is a perspective view of a peripheral portion of a via of a semiconductor device according to a second embodiment;

FIG. 17 is a perspective view of the peripheral portion of the via of the semiconductor device according to the embodiment;

FIG. 18 illustrates a manufacturing process of the semiconductor device according to the embodiment;

FIG. 19 is a perspective view of the peripheral portion of the via of the semiconductor device according to the embodiment;

FIG. 20 is an arrangement diagram of interconnections in a via of a semiconductor device in the comparative example;

FIG. 21 is an arrangement diagram of the interconnections in the via of the semiconductor device in the comparative example;

FIG. 22 is an arrangement diagram of the interconnections in the via of the semiconductor device according to the first embodiment; and

FIG. 23 is an arrangement diagram of the interconnections in the via of the semiconductor device according to the embodiment.

### DETAILED DESCRIPTION

A semiconductor device according to an embodiment includes: a semiconductor substrate; a plurality of interconnect layers disposed at different heights from the semiconductor substrate, each interconnect layer including an interconnection formed therein; and a via formed in a columnar shape extending in the stack direction of the interconnect layers, the via electrically connecting the interconnections of the different interconnect layers, the interconnections including a plurality of intermediate interconnections in contact with the via in the intermediate portion thereof, the intermediate interconnections including a plurality of first type intermediate interconnections passing through the via in a direction perpendicular to the stack direction, and the first type intermediate interconnection of a first one of the interconnect layers and the first type intermediate interconnection of a second one of the interconnect layers intersecting each other in the via.

A semiconductor device and a method of manufacturing the same according to the embodiments will be described below, referring to the attached drawings.

### First Embodiment

First, the structure of a semiconductor device according to a first embodiment will be described.

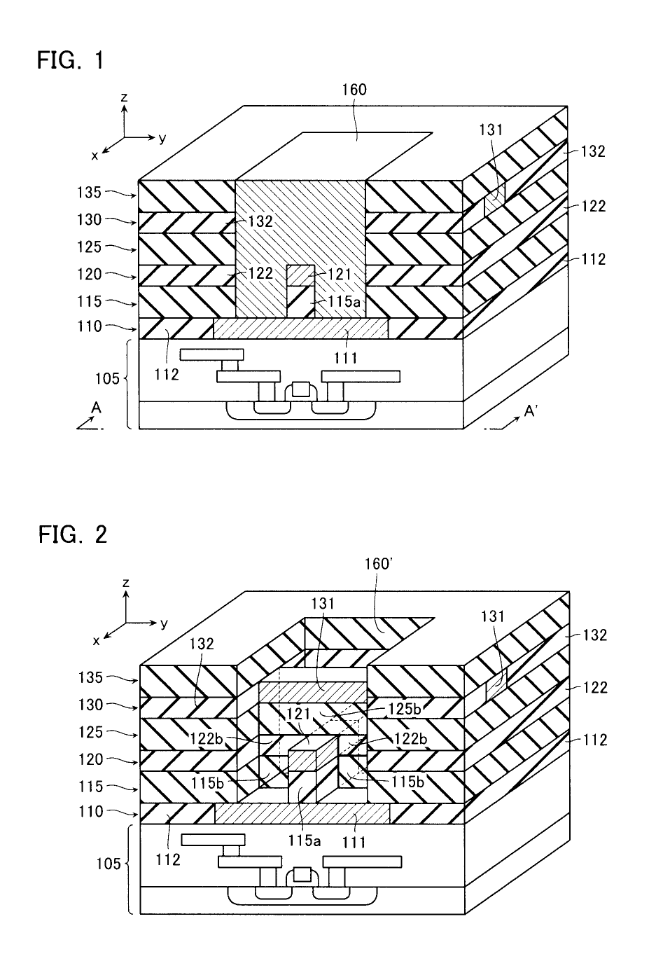

FIG. 1 is a perspective view of the semiconductor device according to this embodiment. FIG. 2 shows the internal structure of the semiconductor device according to this embodiment with a portion of the semiconductor device shown in FIG. 1 being removed for simplicity.

The semiconductor device according to this embodiment includes a silicon (Si) substrate 105 having a transistor and an interconnection formed therein, and a plurality of layers stacked on the silicon substrate 105 in the z-direction. The stacked layers include a lower-layer interconnect layer 110, an insulating layer 115, a first interconnect layer 120, an insulating layer 125, a second interconnect layer 130, and an insulating layer 135. The semiconductor device also includes a via 160 formed in a columnar shape in the z-direction. The via 160 has a lower end at the top surface of the lower-layer interconnect layer 110 and an upper end at the top surface of the insulating layer 135.

The lower-layer interconnect layer 110 includes a lower-layer interconnection 111 and an insulating film 112 formed around the lower-layer interconnection 111. The lower-layer interconnection 111 includes an electrically conductive film such as tungsten (W), aluminum (Al), or copper (Cu). The lower-layer interconnection 111 is connected to the bottom surface of the via 160.

The first interconnect layer 120 includes a first interconnection 121 and insulating films 122 formed around the first interconnection 121. The first interconnection 121 includes an electrically conductive film such as tungsten, aluminum, or copper. The first interconnection 121 is formed passing through the via 160 in the x-direction as shown in FIG. 2.

The second interconnect layer 130 includes a second interconnection 131 and insulating films 132 formed around the second interconnection 131. The second interconnection 131 includes an electrically conductive film such as tungsten, aluminum, or copper. The second interconnection 131 is formed passing through the via 160 in the y-direction as shown in FIG. 2.

Note that interconnections such as the first interconnection 121 and the second interconnection 131 disposed between the top surface and the bottom surface of the via 160 may be hereinafter referred to as “intermediate interconnections.”

The via 160 is formed by embedding electrically conductive films such as tungsten, aluminum, and copper in the through-hole 160′ formed passing through the layers 135, 130, 125, 120 and 115. The via 160 is formed in contact with the second interconnection 131 (a first type intermediate interconnection) and the first interconnection 121 (a first type intermediate interconnection) that are unetched and left in forming the through-hole 160′.

Note that in the portion of the insulating layer 115 that is under the first interconnection 121, an insulating film 115a (hereinafter referred to as a “remaining insulating film”) is formed. The insulating film 115a is unetched and left in forming the via 160 by the manufacturing method as described below.

Similarly, in the portions of the insulating layer 115, the insulating film 122 of the first interconnect layer 120, and the insulating layer 125 that are under the second interconnection 131, remaining insulating films 115b, 122b, and 125b are formed, respectively.

In the above structure, the first interconnection 121 is in contact with the via 160 on the top surface and two side surfaces of the first interconnection 121 except the bottom surface as the contact surface with the remaining insulating film 115a. Similarly, the second interconnection 131 is in contact with the via 160 on the top surface and two side surfaces of the second interconnection 131 except the bottom surface as the contact surface with the remaining insulating film 125b. The lower-layer interconnection 111, the first interconnection 121, and the second interconnection 131 are thus electrically connected by the via 160.

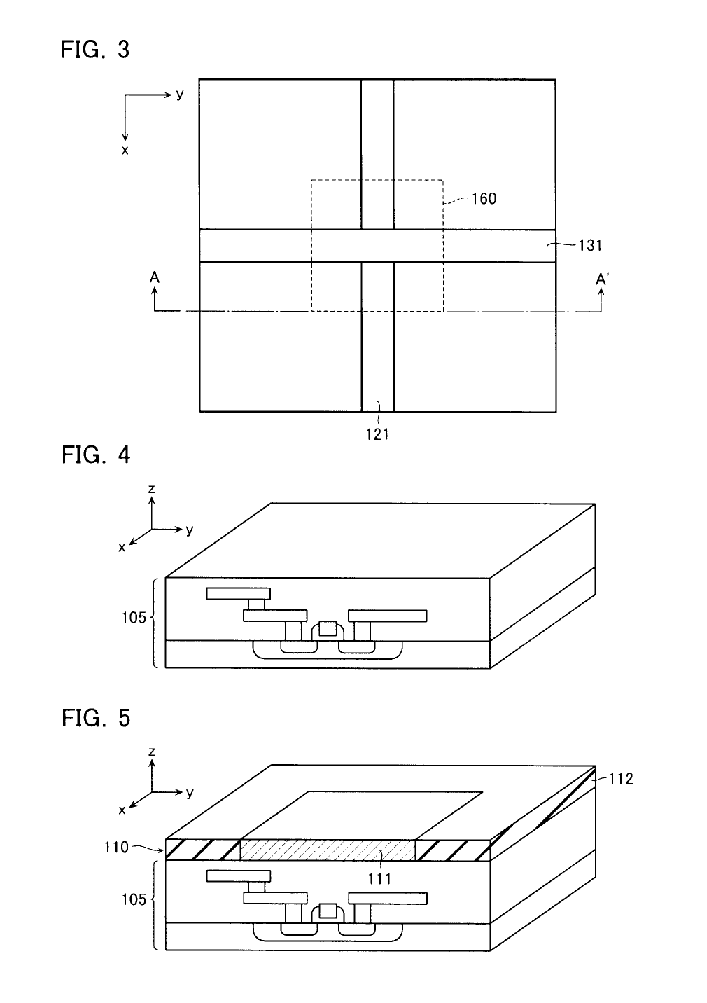

Now, the positional relationship between the first and second interconnections 121 and 131 and the via 160 is described referring to FIG. 3.

FIG. 3 shows the positional relationship between the first interconnection 121 and the second interconnection 131 seen in the z-direction. In the figure, the dotted-line-enclosed region shows the region where the via 160 is formed. Also in the figure, the long and short dashed line shows the A-A′ cross-section in FIG. 1. With reference to FIG. 3, the first interconnection 121 and the second interconnection 131 are formed passing through the via 160 in the x-direction and the y-direction, respectively. In other words, it can be seen that the first interconnection 121 and second interconnection 131 are formed generally perpendicular to each other (intersecting at 90°) in the via 160. In order to have the maximum exposed area of the intermediate interconnection in the via 160, a positions of the first interconnection 121 and the second interconnection 131 in FIG. 3 may be rotated by 45°, thereby allowing the first interconnection 121 and the second interconnection 131 to connect the respective opposite vertices as shown in FIG. 22.

Now, a method of manufacturing the semiconductor device according to this embodiment will be described, referring to FIG. 4-FIG. 10.

First, as shown in FIG. 4, a silicon substrate 105 (a semiconductor substrate) including a transistor and an interconnection formed therein is formed by a well-known method.

Then, as shown in FIG. 5, the lower-layer interconnect layer 110 is formed on the silicon substrate 105. In so doing, first, an insulating material that will serve as the insulating film 112 in the lower-layer interconnect layer 110 is stacked. Then, an insulating material where the lower-layer interconnection 111 is to be formed is removed using a lithography method. Finally, the portion from which the insulating material is removed is embedded with an interconnection material using a damascene method to form the lower-layer interconnection 111 therein. The lower-layer interconnection 111 may be formed to include the region where the via 160 is formed, thereby contacting the entire bottom face of the via 160 with the lower-layer interconnection 111. The contact resistance between the via 160 and the lower-layer interconnection 111 may thus be reduced.

Note that instead of the above process, the lower-layer interconnect layer 110 may be formed using a process in which the lower-layer interconnection 111 is first formed. Specifically, the interconnect ion material of the lower-layer interconnection ill is first stacked. Then, the stacked interconnection material is processed by the lithography method to form the lower-layer interconnection 111. Finally, an insulating material that will serve as the insulating film 112 is embedded over and around the lower-layer interconnection 111. The top surface of the insulating material 111 is then planarized by a process such as CMP until the top surface of the lower-layer interconnection 111 is exposed.

The above is the forming process of the lower-layer interconnect layer 110.

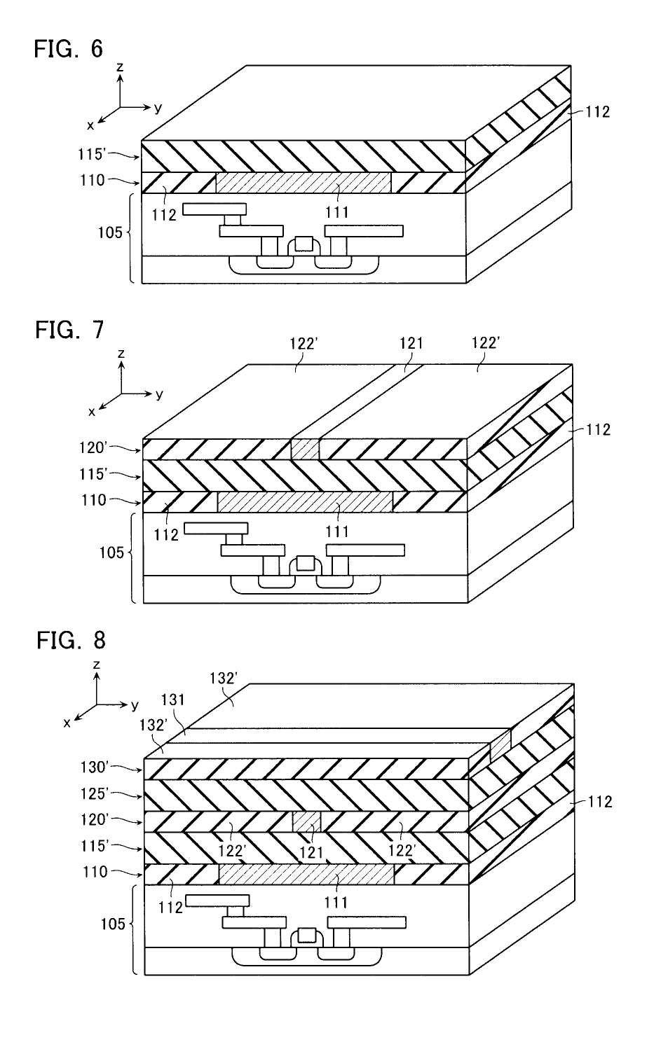

Then, as shown in FIG. 6, a layer 115′ that will serve as the insulating layer 115 is deposited on the lower-layer interconnect layer 110. The layer 115′ may avoid short-circuit between the lower-layer interconnection 111 and the first interconnection 121 formed later.

Then, as shown in FIG. 7, a layer 120′ that will serve as the first interconnect layer 120 is formed on the layer 115′ that will serve as the insulating layer 115. The layer 120′ is formed in a process similar to that of the lower-layer interconnect layer 110. The first interconnection 121 extending in the x-direction is thus formed. Films 122′ that will serve as the insulating films 122 are also around the first interconnection 121 in the y-direction.

Then, as shown in FIG. 8, a layer 125′ that will serve as the insulating layer 125 is formed on the layer 120′ that will serve as the first interconnect layer 120. This layer 125′ may prevent short-circuit between the first interconnection 121 and the second interconnection 131 formed later. Then, a layer 130′ that will serve as the second interconnect layer 130 is formed on the layer 125′ that will serve as the insulating layer 125. The layer 130′ is formed in a process similar to that of the layer 120′ that will serve as the first interconnect layer 120. The second interconnection 131 extending in the y-direction is thus formed. Films 132′ that will serve as the insulating films 132 are also formed around the second interconnection 131 in the x-direction.

The first interconnection 121 and the second interconnection 131 are to be in contact with each other in the intermediate portion of the via 160. The first and second interconnections 121 and 131 are disposed passing through the via 160 and generally perpendicular to each other in the via 160, as shown in FIG. 3.

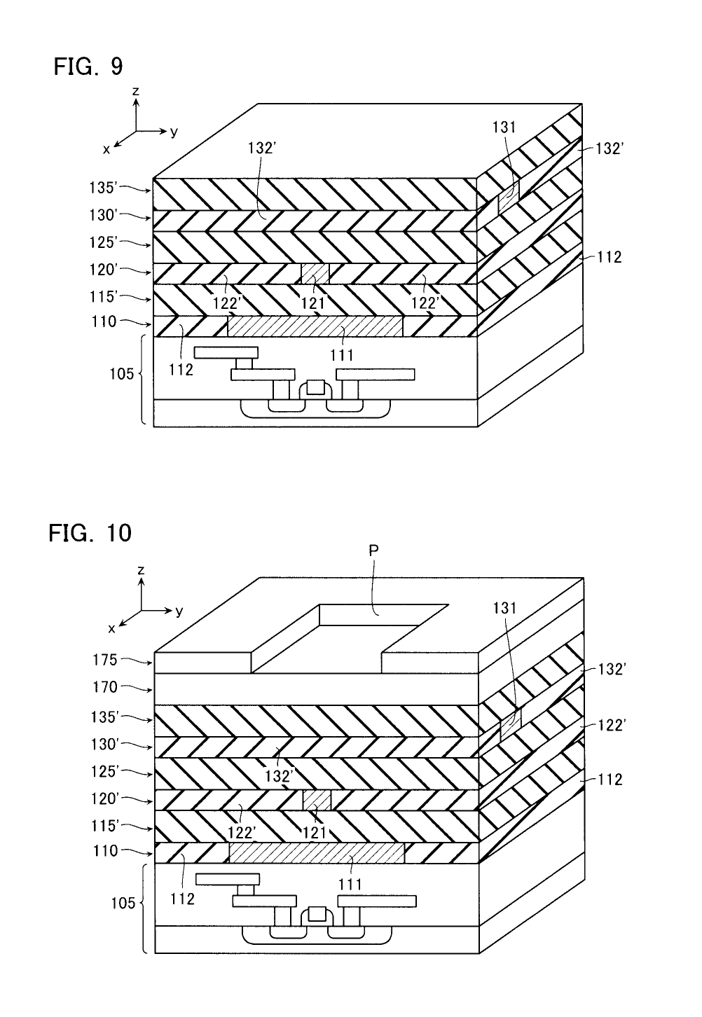

Then, as shown in FIG. 9, a layer 135′ that will serve as the insulating layer 135 is formed on the layer 130′ that will serve as the second interconnect layer 130. This layer 135′ may prevent, when an interconnection is provided in a further upper layer on the second interconnection 131, the layer 135′ short-circuit between the second interconnection 131 and the upper-layer interconnection.

Then, as shown in FIG. 10, a sacrificial film 170 is formed on the layer 135′ that will serve as the insulating layer 135. Then, a resist 175 having a pattern P for the via 160 formed therein is formed on the sacrificial film 170 by a lithography method.

Then, as shown in FIG. 2, a through-hole 160′ is formed by anisotropic etching such as Reactive Ion Etching (RIE) until the top surface of the first interconnect layer 110 is reached. In so doing, the pattern P for the via 160 is transferred to the sacrificial film 170 using the resist 175 as a mask, thereby processing the layers 135′ to 115′. The layers 135′ to 115′ are processed into a vertical or forward tapered shape to provide good embedding characteristics of the materials of the via 160. Note that in forming the through-hole 160′, the second interconnection 131 and the first interconnection 121 are exposed, and the second interconnection 131 and the first interconnections 121 are allowed to remain by performing anisotropic etching with the etching conditions appropriately set, including the etching selectivity of the interconnection materials the insulating materials and the like. Anisotropic etching removes layers 135′ to 115′ except, in the pattern P of the via 160, the second interconnection 131 and the portions 125b, 122b, and 115b thereunder, and the first interconnection 121 and the portion 115a thereunder. As a result, in the through-hole 160′, the top surface and side surfaces of the second interconnection 131 are exposed, and the top surface and side surfaces of the first interconnection 121 are also exposed except the portion under the second interconnection 131.

Finally, a barrier metal and an interconnection material such as tungsten, aluminum, or copper are embedded into the through-hole 160′. The via 160 is thus formed being connected to the first interconnection 121 and second interconnection 131 on the top surface and side surfaces of each. The via 160 and the three interconnections 111, 121, and 131 may thus be electrically connected. Then, unnecessary interconnection materials are removed by CMP.

Using the above manufacturing process, the semiconductor device shown in FIG. 1 may be manufactured.

Now consider that as shown in FIG. 20, intermediate interconnections L1 and L2 are disposed in parallel without intersecting each other within a via formed between a lower-layer interconnection M1 and an upper-layer interconnection M2. If the intermediate interconnection L1 and the intermediate interconnection L2 have enough distance in the y-direction, it is still possible to contact the via with the intermediate interconnections L1 and L2. Because, however, a remaining insulating film under the upper intermediate interconnection L2 is usually forward tapered, insufficient distance between the intermediate interconnections L1 and L2 in the y-direction since misaligned forming L1 and L2 causes the intermediate interconnection L1 to be embedded in the remaining insulating film as shown in FIG. 20, thereby bringing the via and the lower intermediate interconnection L1 into a non-contact state.

In that regard, in this embodiment, as shown in FIG. 3, the first interconnection 121 and second interconnection 131 as the intermediate interconnections are generally perpendicular to each other in the via 160. Some misalignment between the first interconnection 121 and the second interconnection 131 may still prevent the first interconnection 121 from being completely embedded in the remaining insulating films 125b, 122b, and 115b, thereby avoiding the problem in that the first interconnection 121 is not exposed in the via 160.

As described above, this embodiment may provide improved alignment margin between the via and the interconnection or between the interconnections compared to a semiconductor device having a conventional structure that brings the end portion of the interconnection in contact with the via or a structure as shown in the comparative example in FIG. 20.

Because, in this embodiment, the via may be in contact with the top surface and side surfaces of the intermediate interconnections, a larger contact area (a smaller contact resistance) may be provided between the via and the intermediate interconnections compared to the structure in which the end portion of the interconnection is in contact with a side surface of the via.

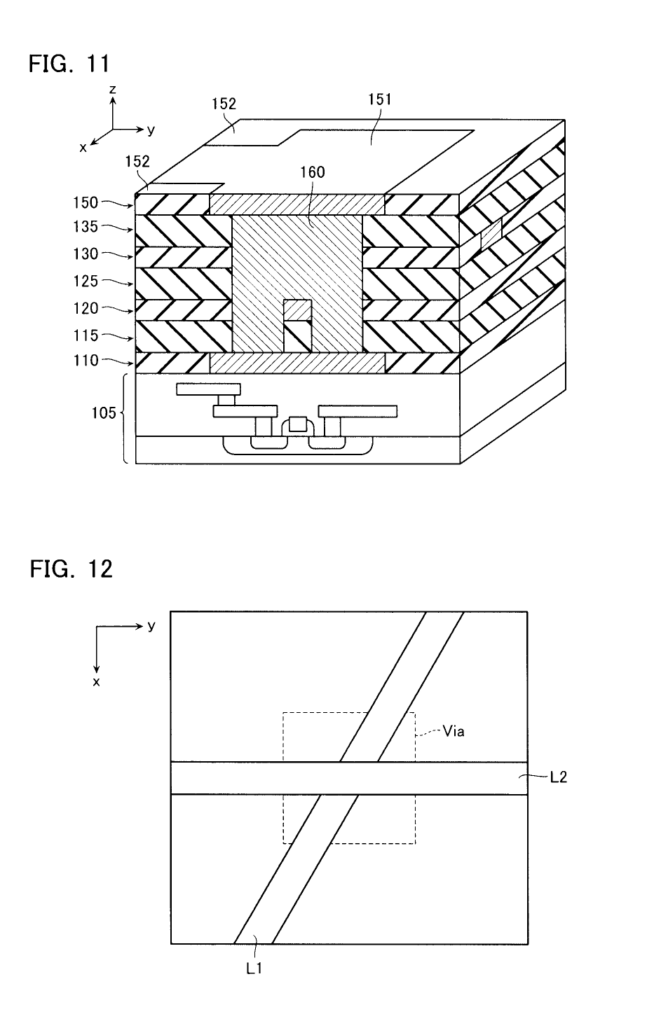

Note that, after completing a structure of FIG. 1, an upper-layer interconnect layer 150 may further be formed on the via 160 and the insulating layer 135 of the semiconductor device as shown in FIG. 1. The upper-layer interconnect layer 150 includes, as shown in FIG. 11, an upper-layer interconnection 151 in contact with the top surface of the via 160 and the insulating film 152 formed around the upper-layer interconnection 151. The upper-layer interconnection 151 may be formed to cover the region where the via 160 is formed, thereby bringing the entire top surface of the via 160 into contact with the upper-layer interconnection 151. This may reduce the contact resistance between the via 160 and the upper-layer interconnection 151. With the manufacturing process as shown in FIG. 11, the via 160 and the four interconnections 111, 121, 131, and 151 may be electrically connected.

Now, some other examples of the semiconductor device according to this embodiment will be described.

FIG. 12 is an example where two intermediate interconnections L1 and L2 (the first type intermediate interconnections) passing through a via are intersecting at an angle of about 60°) (120°. This example may still provide similar effects to those in the example shown in FIG. 3 where the first interconnection 121 and the second interconnection 131 are generally perpendicular to each other.

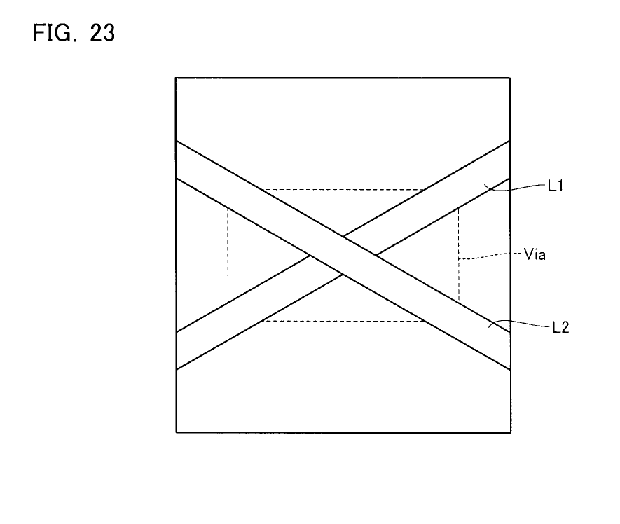

Note that although FIG. 12 shows an intersection angle of about 60°) (120° between the two intermediate interconnections L1 and L2, the intersection angle may be any value except 0 (zero)°. Note that in a lower intermediate interconnection such as the first interconnection 121, the portion under an upper intermediate interconnection such as the second interconnection 131 is not exposed. Therefore, the lower intermediate interconnection has a smaller exposed area in the via, thereby reducing the contact area between the via and the lower intermediate interconnection. It is thus preferable that the intermediate interconnections L1 and L2 passing through the via intersect with each other to reduce their overlap as seen in the z-direction. In other words, the larger (closer to 90°) the intersection angle is between the intermediate interconnections L1 and L2, the larger may the ensured contact area be between the via and the intermediate first interconnection L1 in the same via region. For a via of a rectangular shape, an intermediate interconnection L1 and an intermediate interconnection L2 may not be disposed at 90°, but be disposed to connect the respective opposite vertices, thereby allowing the maximum contact area between the via and the intermediate interconnections L1 and L2 as shown in FIG. 23.

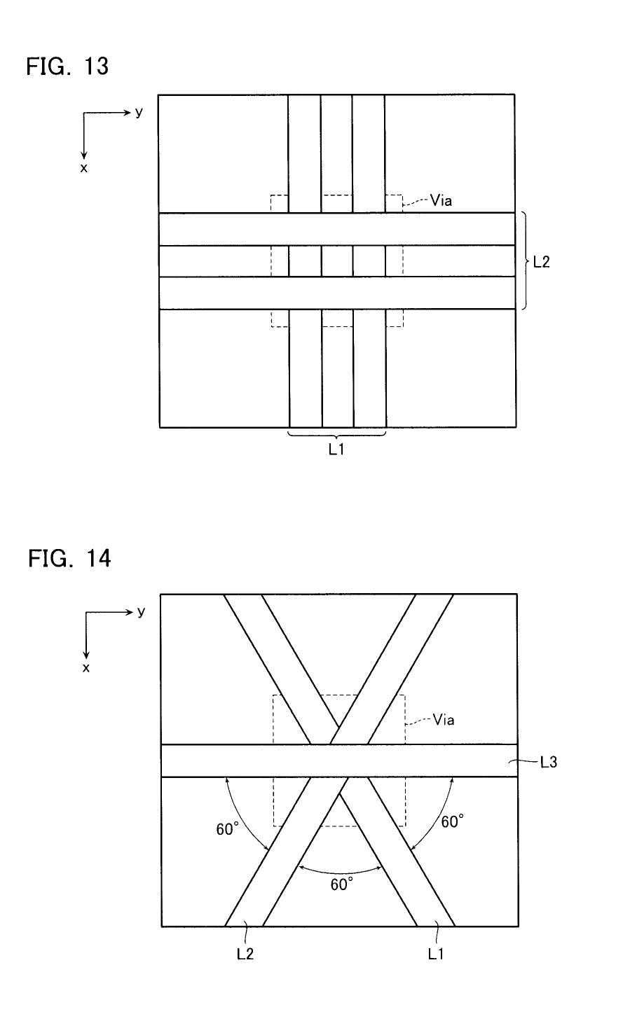

FIG. 13 shows an example where intermediate interconnections L1 and L2 (the first type intermediate interconnections) passing through a via are disposed with two for each. This example is effective when it is hard to widen the intermediate interconnections L1 and L2 due to a side wall transfer method or the like used therefor. Note that the side wall transfer method is a processing method for forming a pattern having a line width of the lithography limit or less. Specifically, a resist pattern is formed having a pitch twice the desired line width. Then, the resist slimming is performed and a first lower layer film is processed into a core material pattern and then the side wall is deposited. Finally, the core material is peeled and a second lower layer film formed under the first lower layer film is processed. The above is the side wall machining process.

In this way, the intermediate interconnections L1 and L2 passing through the via with two for each may generally double the contact area between the via and the intermediate interconnections L1 and L2 compared to the intermediate interconnections L1 and L2 passing through the via with one for each as shown in FIG. 3. Note that with regard to the number of intermediate interconnections passing through the via, only one of the intermediate interconnections L1 and L2 may be two and the other may be one. Further, the number of interconnections passing through the via in each interconnect layer is not limited to two and may be three or more.

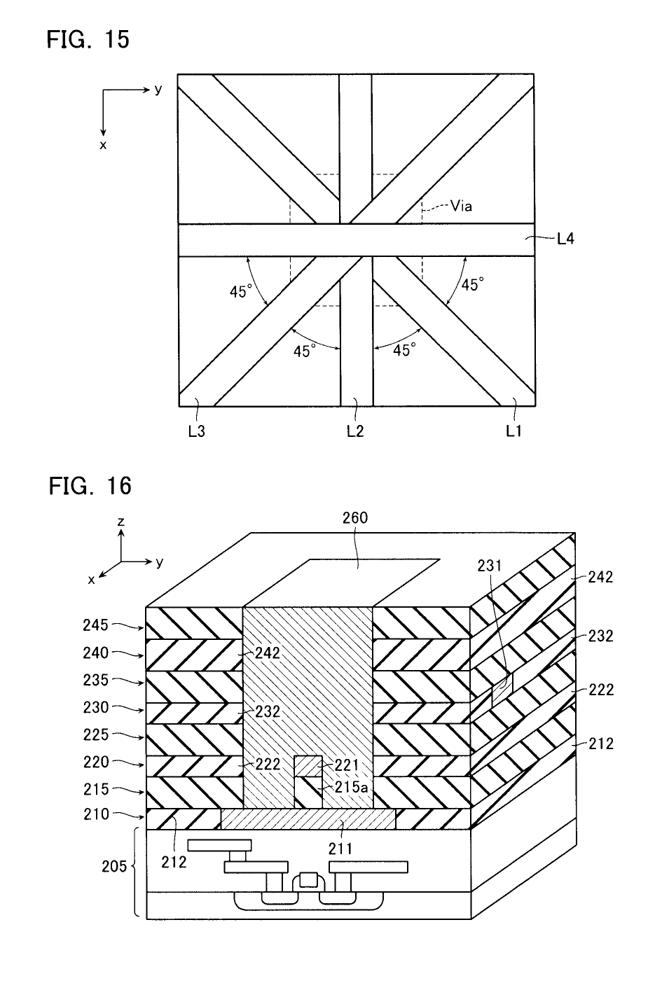

FIG. 14 shows an example arrangement of intermediate interconnections for three interconnect layers each having an intermediate interconnection passing through a via. FIG. 15 shows an example arrangement of intermediate interconnections for four interconnect layers each having an intermediate interconnection passing through a via.

In FIG. 14, the intermediate interconnections L1 to L3 (the first type intermediate interconnections) of three interconnect layers are disposed at the same angle of about 60°. In FIG. 15, the intermediate interconnections L1 to L4 (the first type intermediate interconnections) of four interconnect layers are disposed at the same angle of about 45°. In these examples, the overlapping area between the intermediate interconnections as seen in the z-direction may be smaller than those for other intersection angles. This may ensure a larger contact area between the via and the intermediate interconnections. Note that generally, when the number of interconnect layers having an intermediate interconnection passing through a via is n (n is an integer of 2 or more), the interconnect layers may be disposed at the same angle of 180°/n.

### Second Embodiment

In the second embodiment, among intermediate interconnections contacting a middle portion of a via, an intermediate interconnection contacting to an upper portion of a via is contacted to a side surface of the via at the end portion thereof only. An intermediate interconnection contacting to a lower portion of a via is formed to penetrate the via, like in the first embodiment.

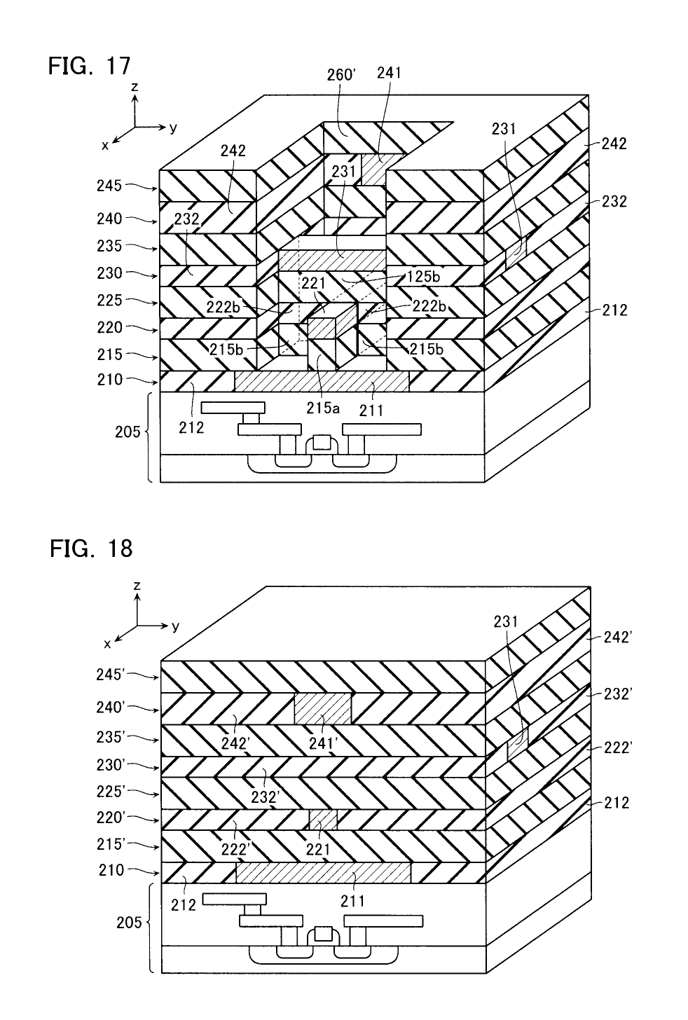

FIG. 16 is a perspective view of a semiconductor device according to a second embodiment. FIG. 17 shows the internal structure of the semiconductor device according to this embodiment with a portion of the semiconductor device shown in FIG. 16 being removed for simplicity.

The semiconductor device according to this embodiment includes a silicon substrate 205 to an insulating layer 235, which are similar to the silicon substrate 105 to the insulating layer 135 of the semiconductor device according to the first embodiment, respectively. Additionally, this embodiment includes a third interconnect layer 240 and an insulating layer 245 on the insulating layer 235.

The third interconnect layer 240 includes, as shown in FIG. 17, a third interconnection 241 (a second type intermediate interconnection) and an insulating film 242 around the third interconnection 241. The third interconnection 241 is formed exposing the end portion thereof on the inner wall of the through-hole 260′ into which the via 260 is embedded, as shown in FIG. 17. The third interconnection 241 is formed having a larger cross sectional area (line width and thickness) than the first interconnection 221 and the second interconnection 231.

Now, a method of manufacturing the semiconductor device according to this embodiment will be described.

First, the process from the formation of the silicon substrate 205 to the stacking of a layer 235′ that will serve as the insulating layer 235 is performed in a similar way to the process from the formation of the silicon substrate 105 to the formation of the layer 135′ that will serve as an insulating layer in the first embodiment.

Then, as shown in FIG. 18, a layer 240′ that will serve as the third interconnect layer 240 is formed on the layer 235′ that will serve as an insulating layer 235. A film 241′ that will serve as the third interconnection 241 extending in the y-direction is thus formed. A film 242′ that will serve as the insulating film 242 is formed around the film 241′ in the y-direction, the film 241′ being that will serve as the third interconnection 241. Then, a layer 245′ that will serve as the insulating layer 245 is stacked on the layer 240′ that will serve as the interconnect layer 240. This layer 245′ may prevent, when an interconnection is provided in a further upper layer on the third interconnection 241, short-circuit between the third interconnection 241 and the upper-layer interconnection.

Then, as shown in FIG. 17, a through-hole 260′ is formed from the top surface of the layer 245′ that will serve as the insulating layer 245 to the top surface of the lower-layer interconnect layer 210. In so doing, the first interconnection 211 (the first type intermediate interconnection) and the second interconnection 231 (the first type intermediate interconnection) each having a smaller cross sectional area are unremoved as in the first embodiment. The film 241′ that will serve as the third interconnection 241 (the second type intermediate interconnection) having a larger cross sectional area is removed. The end portion of the third interconnection 241 and a side surface of the via 260 formed later may thus be in contact with each other. In this embodiment, the third interconnection 241 has a larger cross sectional area than the first interconnection 211 and second interconnection 231 formed at a lower position than the third interconnection 241. This allows, the third interconnection 241 to have a certain degree of contact area, thereby decreasing the contact resistance, although it contacts with the via 260 only at a side surface thereof. The third interconnection 241 is thus formed.

Finally, as shown in FIG. 16, the through-hole 260′ is embedded with a barrier metal and an interconnection material such as tungsten, aluminum, or copper. The via 260 is thus formed, thereby electrically connecting the lower-layer interconnection 211, the first interconnection 221, the second interconnection 231, and the third interconnection 241. Then, unnecessary interconnection materials are removed by CMP.

Using the above manufacturing process, the semiconductor device shown in FIG. 16 may be manufactured.

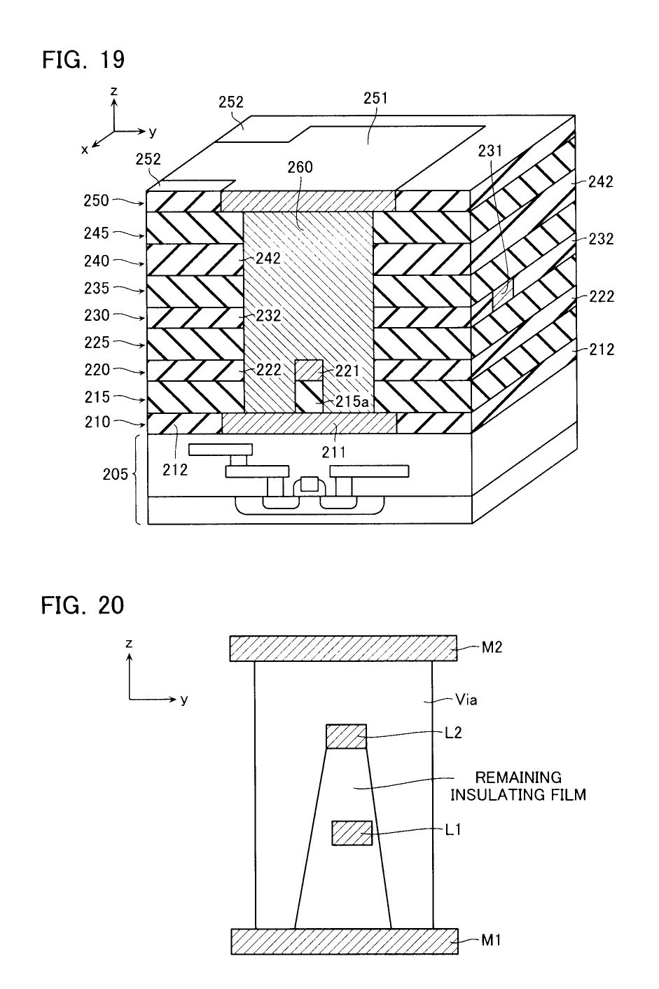

Note that as shown in FIG. 19, as in the first embodiment, after the above manufacturing process, an upper-layer interconnect layer 250 may be formed on the via 260 and insulating layer 245. The upper-layer interconnect layer 250 includes an upper-layer interconnection 251 disposed to cover the region where the via 260 is formed, and an insulating film 252 disposed around the upper-layer interconnection 251.

Also, like the third interconnection 241 in this embodiment, a plurality of interconnect layers each having an intermediate interconnection in contact with side surface of a via may be stacked. In this case, a similar process to that in FIG. 18 may be repeated by the number of desired layers.

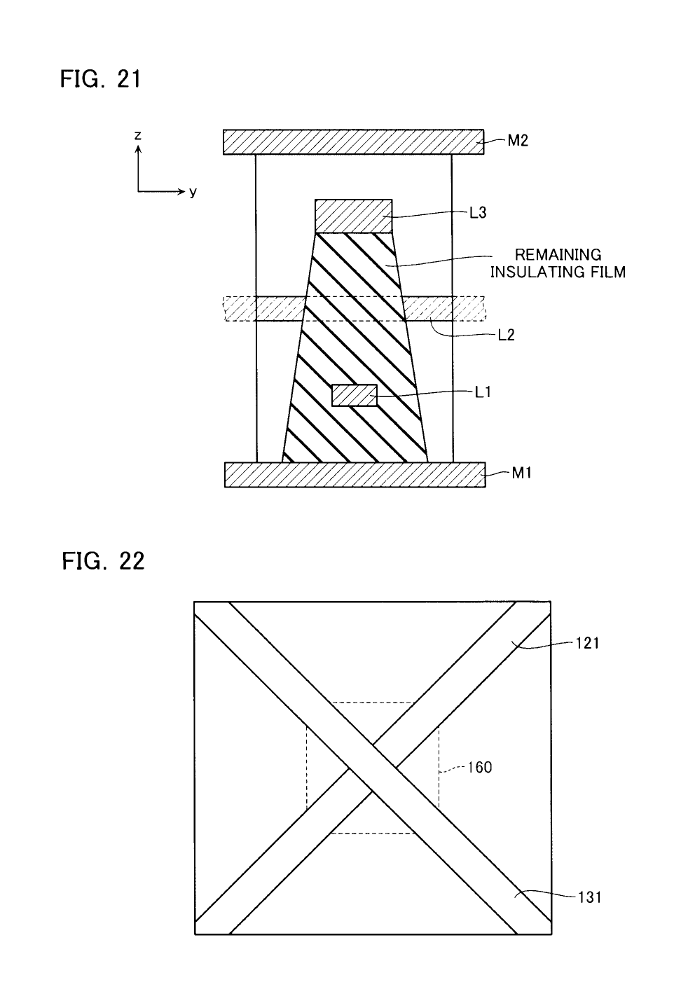

Generally, in semiconductor devices, an interconnection is thicker and has a larger line width in upper layers. Now consider, therefore, that for example, as shown in FIG. 21, among intermediate interconnections L1 to L3 in contact with an intermediate portion of a via formed from a lower-layer interconnection M1 to an upper-layer interconnection M2, an upper intermediate interconnection L3 is large enough to cover the most part of the via. If, in this case, the intermediate interconnections L1 to L3 all remain in the via as in the first embodiment, a large remaining insulating film is provided under the upper intermediate interconnection L3. This may reduce the contact area between the via and the lower intermediate interconnections L1 and L2 and the contact area between the via and the lower-layer interconnection M1 in contact with the bottom surface of the via.

In that regard, this embodiment may provide a similar effect to that in the first embodiment and also provide a semiconductor device having more stacks without loosing the contact area between the lower intermediate interconnection and the via by bringing the upper intermediate interconnection having a larger cross-section into contact with the via side surface.

### [Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate;
a plurality of interconnect layers disposed at different heights from the semiconductor substrate, each interconnect layer comprising an interconnection formed therein; and
a via formed in a columnar shape extending in the stack direction of the interconnect layers, the via electrically connecting the interconnections of the different interconnect layers,
the interconnections including a plurality of intermediate interconnections in contact with the via in the intermediate portion thereof,
the intermediate interconnections including a plurality of first type intermediate interconnections passing through the via in a direction perpendicular to the stack direction, and
the first type intermediate interconnection of a first one of the interconnect layers and the first type intermediate interconnection of a second one of the interconnect layers intersecting each other in the via.

2. The semiconductor device according to claim 1, wherein
the first type intermediate interconnection comprises a plurality of interconnections extending in parallel with each other in a certain interconnect layer.

3. The semiconductor device according to claim 1, wherein
the first type intermediate interconnections are disposed in the via at substantially the same angle seen in the stack direction.

4. The semiconductor device according to claim 1, wherein
the intermediate interconnections further including a second type intermediate interconnection that is, in contact with a side surface of the via at the end portion thereof, and is electrically connected to the first intermediate interconnection.

5. The semiconductor device according to claim 4, wherein
the second type intermediate interconnection has a larger cross sectional area than the first type intermediate interconnection.

6. The semiconductor device according to claim 1, wherein
the first intermediate interconnection is in contact with the via, on the top surface and both side surfaces thereof.

7. The semiconductor device according to claim 1, wherein
the interconnections further include a lower-layer interconnection in contact with the via on the bottom surface thereof.

8. The semiconductor device according to claim 1, wherein
the interconnections further include an upper-layer interconnection in contact with the via on the top surface thereof.

9. A semiconductor device comprising:
a semiconductor substrate;
a plurality of interconnect layers disposed at different heights from the semiconductor substrate, each interconnect layer comprising an interconnection formed therein; and
a via formed in a columnar shape extending in the stack direction of the interconnect layers, the via electrically connecting the interconnections of the different interconnect layers,
the interconnections including a plurality of intermediate interconnections in contact with the via in the intermediate portion thereof,
the intermediate interconnections including a plurality of first type intermediate interconnections, and
the first type intermediate interconnection of a first one of the interconnect layers and the first type intermediate interconnection of a second one of the interconnect layers intersecting each other in the via seen in the stack direction.

10. The semiconductor device according to claim 9, wherein
the first type intermediate interconnection comprises a plurality of interconnections extending in parallel with each other a certain interconnect layer.

11. The semiconductor device according to claim 9, wherein
the first type intermediate interconnections are disposed in the via at substantially the same angle seen in the stack direction.

12. The semiconductor device according to claim 9, wherein
the intermediate interconnections further including a second type intermediate interconnection that is, in contact with a side surface of the via at the end portion thereof, and is electrically connected to the first intermediate interconnection.

13. The semiconductor device according to claim 12. wherein
the second type intermediate interconnection has a larger cross sectional area than the first type intermediate interconnection.

14. The semiconductor device according to claim 9, wherein
the first intermediate interconnection is in contact with the via, on the top surface and both side surfaces thereof.

15. The semiconductor device according to claim 9, wherein
the interconnections further include a lower-layer interconnection in contact with the via on the bottom surface thereof.

16. The semiconductor device according to claim 9, wherein
the interconnections further include an upper-layer interconnection in contact with the via on the top surface thereof.

17. A method of manufacturing a semiconductor device, comprising:
forming a semiconductor substrate;
sequentially stacking a first interconnect layer comprising a first interconnection formed therein and a second interconnect layer comprising a second interconnection formed therein on the semiconductor substrate;
forming a via in a columnar shape extending in the stack direction of the first and second interconnect layers, the via electrically connecting the first and second interconnections;
in stacking the first and second interconnect layers, forming the second interconnection to intersect with the first interconnection in the via seen in the stack direction; and
in forming the via,
forming a through-hole so that the top surfaces of the first and second interconnections are exposed, and
embedding a material of the via in the through-hole.

18. The method of manufacturing a semiconductor device according to claim 17, further comprising:
before forming the via, stacking a third interconnect layer comprising a third interconnection formed therein on the semiconductor substrate; and
in forming the through-hole, removing the third interconnection in the via to expose a cross-section of the third interconnection on a side surface of the through-hole.

19. The method of manufacturing a semiconductor device according to claim 17, further comprising,
before stacking the first interconnect layer, stacking a lower-layer interconnect layer on the semiconductor substrate, the lower-layer interconnect layer comprising a lower-layer interconnection formed therein, the lower-layer interconnection being in contact with the via on a bottom surface thereof.

20. The method of manufacturing a semiconductor device according to claim 17, further comprising:
after forming the via, stacking an upper-layer interconnect layer comprising an upper-layer interconnection formed therein, the upper-layer interconnection being in contact with the via on a top surface thereof.
